(19) United States
(12) Patent Application Publication
(10) Pub. No.: US 2026/0370210 A1
(43) Pub. Date: Nov. 19, 2026

(54) MICROACOUSTIC SURFACE ACOUSTIC WAVE (SAW) RESONATOR ON ELECTRICALLY NON-CONDUCTIVE SUBSTRATE AND A METHOD OF MANUFACTURE

(71) Applicant: RF360 Singapore Pte. Ltd., Singapore (SG)

(72) Inventor: Ulrike Monika Roesler, Hebertshausen (DE)

(21) Appl. No.: 19/208,374

(22) Filed: May 14, 2025

(51) Int. Cl. H03H 9/02; H03H 3/10; H03H 9/145; H03H 9/25

(52) U.S. Cl. CPC H03H 9/02834; H03H 3/10; H03H 9/02559; H03H 9/02574; H03H 9/145; H03H 9/25

(57) ABSTRACT

In a normal range of temperatures in which a hand-held electronic device is operated, a silicon substrate in a microacoustic surface acoustic wave (SAW) resonator is a poor conductor of electricity, and thereby avoids energy losses as current through the substrate. When either environmental conditions or operational conditions cause the temperature of the silicon substrate to increase, however, the electrical conductivity of the silicon substrate also increases, allowing energy to be lost through the substrate, and causing reductions in both efficiency and performance. An exemplary microacoustic SAW resonator includes a substrate material that remains electrically non-conducting even at higher temperatures (e.g., greater than 150 °C) to reduce energy losses while continuing to be thermally conductive for heat dissipation. The microacoustic SAW resonator also includes a fluorinated silicon dioxide (SiOF) bonding layer to improve the temperature coefficient of frequency (TCF) of the piezoelectric layer.

### TECHNICAL FIELD

This disclosure relates generally to wireless transceivers and other components that employ filters and, more specifically, to a microacoustic resonator with improved high temperature performance.

### BACKGROUND

Electronic devices use radio-frequency (RF) signals to communicate information. These radio-frequency signals enable users to talk with friends, download information, share pictures, remotely control household devices, and receive global positioning information. To transmit or receive the radio-frequency signals within a given frequency band, the electronic device may use filters to pass signals within the frequency band and to suppress (e.g., attenuate) jammers or noise at frequencies outside of the frequency band. It can be challenging, however, to design a filter that provides filtering for RF applications, including those that utilize frequencies above three (3) gigahertz (GHz), such as for the 5th-generation (5G) and higher generations of cellular network technology. In particular, one of the challenges is to design filters that operate with consistency in electronic devices that are subject to a wide range of conditions.

### SUMMARY

An apparatus is disclosed that includes a microacoustic surface acoustic wave (SAW) resonator on an electrically non-conductive substrate. Related methods of manufacturing a microacoustic SAW resonator including an electrically non-conductive substrate are also disclosed. In a normal range of temperatures in which a hand-held electronic device is operated, a silicon substrate in a microacoustic SAW resonator is a poor conductor of electricity, and thereby avoids energy losses as current through the substrate. When either environmental conditions or operational conditions cause the temperature of the silicon substrate to increase, however, the electrical conductivity of the silicon substrate also increases, allowing energy to be lost through the substrate, and causing reductions in both efficiency and performance. An exemplary microacoustic SAW resonator includes a substrate material that remains electrically non-conducting even at higher temperatures (e.g., greater than 150 °C) to reduce energy losses while continuing to be thermally conductive for heat dissipation. The microacoustic SAW resonator also includes a fluorinated silicon dioxide (SiOF) bonding layer to improve the temperature coefficient of frequency (TCF) of the resonator. In some examples, the substrate material may be polycrystalline spinel, such as magnesium aluminate (MgAl₂O₄).

In an example aspect, a microacoustic SAW resonator is disclosed. The microacoustic SAW resonator includes a substrate comprising a substrate material having an electrical conductivity less than 0.0001 Siemens/meter (10⁻⁴ S/m) at a temperature of one hundred fifty degrees Celsius (150 °C). The microacoustic SAW resonator also includes a piezoelectric layer. The microacoustic SAW resonator also includes a first bonding layer comprising fluorinated silicon dioxide (SiOF) disposed between the piezoelectric layer and the substrate.

In another example aspect, a method for fabricating a microacoustic SAW resonator is disclosed. The method includes forming a substrate comprising a substrate material comprising a polycrystalline spinel having an electrical conductivity that is less than 0.0001 Siemens/meter (10⁻⁴ S/m) at a temperature of one hundred fifty degrees Celsius (150 °C). The method also includes forming a piezoelectric layer on a first bonding layer. The method also includes forming the first bonding layer comprising fluorinated silicon dioxide (SiOF) between the substrate and the piezoelectric layer.

In another example aspect, a microacoustic SAW resonator is disclosed. The microacoustic SAW resonator includes a substrate comprising a polycrystalline spinel comprising magnesium aluminate (MgAl₂O₄). The microacoustic SAW resonator also includes a piezoelectric layer. The microacoustic SAW resonator also includes a first bonding layer comprising fluorinated silicon dioxide (SiOF) disposed between the piezoelectric layer and the substrate.

### BRIEF DESCRIPTION OF DRAWINGS

FIG. 1 illustrates an example operating environment for operating a microacoustic surface acoustic wave (SAW) resonator including a substrate that remains electrically non-conductive above a temperature of one hundred fifty degrees Celsius (150 °C) and comprising a bonding layer of fluorinated silicon dioxide (SiOF);

FIG. 2 illustrates an example wireless transceiver including at least one microacoustic SAW resonator including a substrate that remains electrically non-conductive above a temperature of 150 °C and comprising a bonding layer of SiOF;

FIG. 3 illustrates example components of a microacoustic SAW resonator including a substrate that remains electrically non-conductive above a temperature of 150 °C and comprising a bonding layer of SiOF;

FIG. 4 is a three-dimensional (3D) perspective view of a first example of a microacoustic SAW resonator including a substrate that remains electrically non-conductive above a temperature of 150 °C and comprising a bonding layer of SiOF;

FIG. 5 is a 3D perspective view of a second example of a microacoustic SAW resonator including a substrate that remains electrically non-conductive above a temperature of 150 °C and comprising a bonding layer of SiOF;

FIG. 6 is a flowchart illustrating a process of fabricating a microacoustic SAW resonator including a layer of SiOF and a substrate that remains electrically non-conductive above a temperature of 150 °C and higher;

FIG. 7 is a block diagram of an exemplary wireless communication device that includes a substrate that remains electrically non-conductive above a temperature of 150 °C and comprising a bonding layer of SiOF; and

FIG. 8 is a block diagram of an exemplary processor-based system that can include a substrate that remains electrically non-conductive above a temperature of 150 °C and comprising a bonding layer of SiOF).

### DETAILED DESCRIPTION

An apparatus is disclosed that includes a microacoustic surface acoustic wave (SAW) resonator on an electrically non-conductive substrate. Related methods of manufacturing a microacoustic SAW resonator including an electrically non-conductive substrate are also disclosed. In a normal range of temperatures in which a hand-held electronic device is operated, a silicon substrate in a microacoustic SAW resonator is a poor conductor of electricity, and thereby avoids energy losses as current through the substrate. When either environmental conditions or operational conditions cause the temperature of the silicon substrate to increase, however, the electrical conductivity of the silicon substrate also increases, allowing energy to be lost through the substrate, and causing reductions in both efficiency and performance. An exemplary microacoustic SAW resonator includes a substrate material that remains electrically non-conducting even at higher temperatures (e.g., greater than 150 °C) to reduce energy losses while continuing to be thermally conductive for heat dissipation. The microacoustic SAW resonator also includes a fluorinated silicon dioxide (SiOF) bonding layer to improve the temperature coefficient of frequency (TCF) of the resonator. In some examples, the substrate material may be polycrystalline spinel, such as magnesium aluminate (MgAl₂O₄).

An electronic device may use filters to pass radio-frequency (RF) signals transmitted or received within a given frequency and to suppress (e.g., attenuate) jammers or noise-having frequencies outside of the frequency band. Electroacoustic devices (e.g., “acoustic filters”) can be used to filter high-frequency signals in many applications, such as those with frequencies that are greater than 100 megahertz (MHz). An acoustic filter is tuned to pass certain frequencies (e.g., frequencies within its passband) and attenuate other frequencies (e.g., frequencies that are outside of its passband). Using a piezoelectric material, the acoustic filter operates by transforming an electrical signal wave that is applied to an electrical conductor into an acoustic wave (e.g., an acoustic signal wave) that forms across the piezoelectric material. The acoustic wave is then converted back into an electrical filtered signal. The acoustic filter can include an electrode structure that transforms or converts between the electromagnetic and acoustic waves.

The acoustic wave features a velocity having a magnitude that is significantly less than that of a velocity of the electromagnetic wave. Generally, the magnitude of the propagation velocity of a wave is proportional to a size of a wavelength of the wave. Consequently, after conversion of the electrical signal wave into the acoustic signal wave, the wavelength of the acoustic signal wave is significantly smaller than the wavelength of the electrical signal wave. The resulting smaller wavelength of the acoustic signal wave enables filtering to be performed using a smaller filter device. This permits acoustic filters to be used in space-constrained devices, including portable electronic devices such as cellular phones. These acoustic filters can be referred to as microacoustic filters that include microacoustic resonators.

It can be challenging to design a microacoustic filter that can provide filtering for higher frequencies, such as those used with Wi-Fi® at 2.4 gigahertz (GHz) and higher, 3 GHz to 7 GHz frequencies, and frequencies between 7 and 18 GHz and higher in radio-frequency (RF) applications. In particular, it can be challenging to design a filter that operates under all the conditions, such as temperature extremes, experienced by cell phones and other types of communications devices.

To address these challenges, some techniques implement microacoustic filters including microacoustic resonators. One example of a microacoustic resonator is a microacoustic SAW resonator that includes a layer stack including a thin film of piezoelectric material on a substrate. Making the thin-film piezoelectric layer too thin may cause it to not have sufficient static capacitance for a filter circuit, unless the size (e.g., area) of the piezoelectric layer is increased. However, increasing the size of a microacoustic resonator may be prohibitive for the electronic devices in which it may be employed. A thin-film piezoelectric layer with a greater thickness may be preferable with regard to capacitance but with a greater thickness of the piezoelectric material comes an increase in the change in performance with a change in temperature, known as temperature coefficient of frequency (TCF). This is particularly problematic in some RF applications, such as cellular telephones, which may experience a wide variety of environmental conditions, including high temperatures. Including a layer of SiOF in the microacoustic resonator stack improves the bonding of the piezoelectric layer to a substrate and also provides TCF compensation, making the TCF of the stack more positive.

The effects of TCF on a microacoustic thin-film SAW resonator may include a significant frequency shift in response to an increase in temperature, which may lead to an unwanted shift of the filter passband. In addition, a microacoustic thin-film SAW resonator may also suffer from an increase in insertion loss as temperatures increase. Conventional thin-film SAW resonator stacks may include silicon substrates, which are inexpensive and for which there are well-known manufacturing methods. However, silicon is a semiconducting material having an electrical conductivity that increases with temperature. Thus, it has been found that microacoustic resonators including silicon substrates may lose a significant amount of energy in the form of electricity conducted through the substrate. Alternative materials that maintain a low electrical conductivity, such as quartz, can be used instead of silicon, but such materials may also be poor conductors of heat. Thus, when the acoustic activity in the piezoelectric layer causes the temperature of the piezoelectric layer to increase, the excess heat cannot be easily dissipated through the substrate. For this reason, an exemplary microacoustic thin-film SAW resonator includes a substrate comprising an electrically non-conductive material. In some examples, the substrate may have an electrical conductivity that remains less than 0.0001 Siemens/meter (10⁻⁴ S/m) even at temperatures exceeding one hundred fifty degrees Celsius (150 °C).

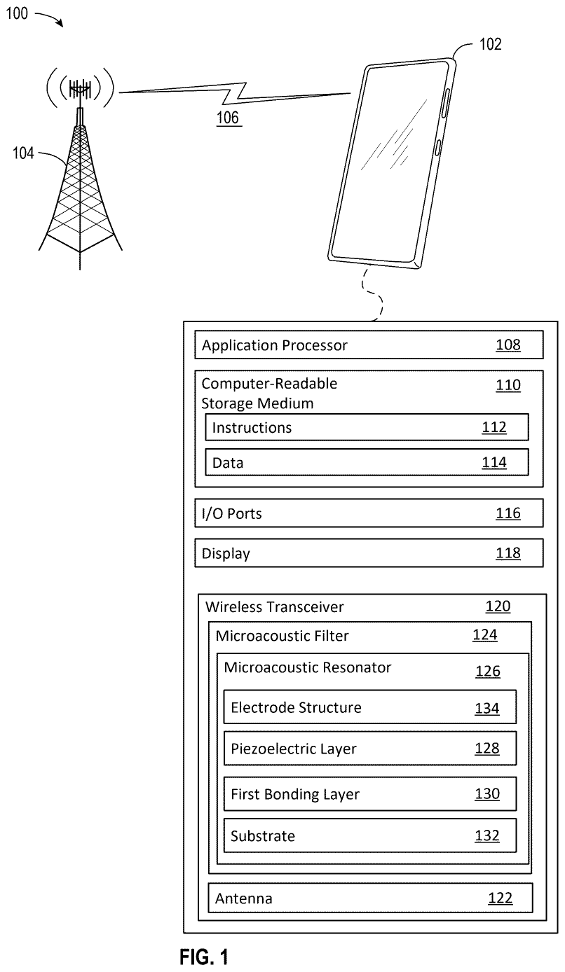

FIG. 1 illustrates an example environment 100 for operating a microacoustic SAW resonator including a substrate that remains non-conductive at high temperatures and also including a first bonding layer of SiOF to bond the piezoelectric layer to the substrate and provide TCF compensation. In the environment 100, a computing device 102 communicates with a base station 104 through a wireless communication link 106 (wireless link 106). In this example, the computing device 102 is depicted as a smartphone. However, the computing device 102 can be implemented as any suitable computing or electronic device, such as a modem, a cellular base station, a broadband router, an access point, a cellular phone, a gaming device, a navigation device, a media device, a laptop computer, a desktop computer, a tablet computer, a wearable computer, a server, a network-attached storage (NAS) device, a smart appliance or other internet of things (IoT) device, a medical device, a vehicle-based communication system, a radar, a radio apparatus, and so forth. Use of a microacoustic resonator is not limited to acoustic filters for wireless communication as a microacoustic filter can be applied in any technological field where such filtering is useful.

The base station 104 communicates with the computing device 102 via the wireless link 106, which can be implemented as any suitable type of wireless link. Although depicted as a tower of a cellular network, the base station 104 can represent or be implemented as another device, such as a satellite, a server device, a terrestrial television broadcast tower, an access point, a peer-to-peer device, a mesh network node, and so forth. Therefore, the computing device 102 may communicate with the base station 104 or another device via a wireless connection.

The wireless link 106 can include a downlink of data or control information communicated from the base station 104 to the computing device 102, an uplink of other data or control information communicated from the computing device 102 to the base station 104, or both a downlink and an uplink. The wireless link 106 can be implemented using any suitable communication protocol or standard, such as 2nd-generation (2G), 3rd-generation (3G), 4th-generation (4G), 5th-generation (5G), or 6th-generation (6G) cellular; IEEE 802.11 (e.g., Wi-Fi®); IEEE 802.15 (e.g., Bluetooth®); IEEE 802.16 (e.g., WiMAX®); and so forth. In some implementations, the wireless link 106 may wirelessly provide power and the base station 104 or the computing device 102 may comprise a power source.

As shown, the computing device 102 includes an application processor 108 and a computer-readable storage medium 110 (CRM 110). The application processor 108 can include any type of processor, such as a multi-core processor, that executes processor-executable code stored by the CRM 110. The CRM 110 can include any suitable type of data storage media, such as volatile memory (e.g., random access memory (RAM)), non-volatile memory (e.g., Flash memory), optical media, magnetic media (e.g., disk), and so forth. In the context of this disclosure, the CRM 110 is implemented to store instructions 112, data 114, and other information of the computing device 102, and thus does not include transitory propagating signals or carrier waves.

The computing device 102 can also include input/output ports 116 (I/O ports 116) and a display 118. The I/O ports 116 enable data exchanges or interaction with other devices, networks, users, or the environment. The I/O ports 116 can include serial ports (e.g., universal serial bus (USB) ports), parallel ports, audio ports, infrared (IR) ports, user interface ports such as a touchscreen, and so forth. The display 118 presents graphics of the computing device 102, such as a user interface associated with an operating system, program, or application. Alternatively or additionally, the display 118 can be implemented as a display port or virtual interface through which graphical content of the computing device 102 is presented.

A wireless transceiver 120 of the computing device 102 provides connectivity to respective networks and other electronic devices connected therewith. The wireless transceiver 120 can facilitate communication over any suitable type of wireless network, such as a wireless local area network (WLAN), peer-to-peer (P2P) network, mesh network, cellular network, ultra-wideband (UWB) network, wireless wide-area-network (WWAN), and/or wireless personal-area-network (WPAN). In the context of the example environment 100, the wireless transceiver 120 enables the computing device 102 to communicate with the base station 104 and networks connected therewith. However, the wireless transceiver 120 can also enable the computing device 102 to communicate “directly” with other devices or networks.

The wireless transceiver 120 includes circuitry and logic for transmitting and receiving communication signals via an antenna 122. Components of the wireless transceiver 120 can include amplifiers, switches, mixers, analog-to-digital converters, filters, and so forth for conditioning the communication signals (e.g., for generating or processing signals). The wireless transceiver 120 can also include logic to perform in-phase/quadrature (I/Q) operations, such as synthesis, encoding, modulation, decoding, demodulation, and so forth. In some cases, components of the wireless transceiver 120 are implemented as separate transmitter and receiver entities. Additionally or alternatively, the wireless transceiver 120 can be realized using multiple or different sections to implement respective transmitting and receiving operations (e.g., separate transmit and receive chains). In general, the wireless transceiver 120 processes data and/or signals associated with communicating data of the computing device 102 over the antenna 122.

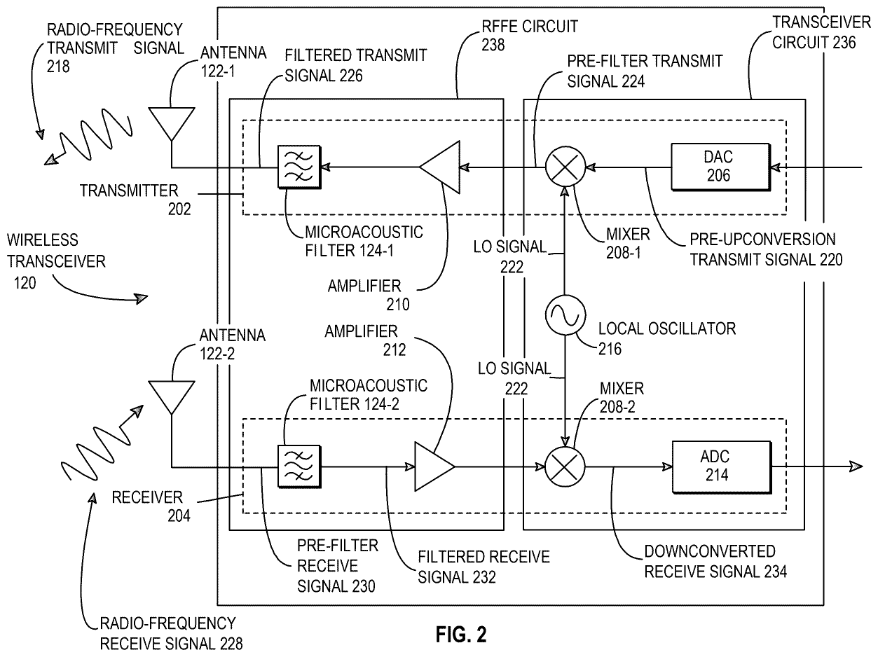

In the example shown in FIG. 1, the wireless transceiver 120 includes at least one microacoustic filter 124 including at least one microacoustic SAW resonator (also referred to herein as “microacoustic resonator”) 126, which may operate in a longitudinal mode. In some implementations, the wireless transceiver 120 includes multiple microacoustic filters 124, which can be formed from microacoustic resonators 126 arranged in series, in parallel, in a ladder structure, in a lattice structure, or some combination thereof. The microacoustic resonator 126 includes a piezoelectric layer 128, a first bonding layer 130 comprising SiOF, and a substrate 132. The microacoustic resonator 126 also includes an electrode structure 134 on the piezoelectric layer 128. The substrate 132 is electrically non-conductive, having an electrical conductivity that remains below 0.0001 Siemens/meter (10⁻⁴ S/m) even at temperatures exceeding 150 °C (e.g., approx. 423 degrees Kelvin). In contrast, undoped silicon (Si) has an electrical conductivity that increases from approximately 0.01 (10⁻² S/m) at room temperature to approximately 0.3 S/m at 150 °C. Therefore, the microacoustic filter 124 loses significantly less energy as leakage currents through the substrate 132 compared to microacoustic filters having Si substrates, while still providing thermal conductivity in a range between 17 and 5 W/mK (Watts per meter Kelvin) in the anticipated range of operating temperatures of the microacoustic filter 124 in the computing device 102. The microacoustic filter 124 is further described with respect to FIG. 2. With the above improvements, the microacoustic filter 124 may be designed to support frequency ranges up to 3 GHz and higher.

FIG. 2 illustrates an example wireless transceiver 120. In the depicted configuration, the wireless transceiver 120 includes a transmitter 202 and a receiver 204, which are respectively coupled to a first antenna 122-1 and a second antenna 122-2. In other implementations, the transmitter 202 and the receiver 204 can be connected to a same antenna through a duplexer (not shown). The transmitter 202 is shown to include at least one digital-to-analog converter 206 (DAC 206), at least one first mixer 208-1, at least one amplifier 210 (e.g., a power amplifier), and at least one first microacoustic filter 124-1. The receiver 204 includes at least one second microacoustic filter 124-2, at least one amplifier 212 (e.g., a low-noise amplifier), at least one second mixer 208-2, and at least one analog-to-digital converter 214 (ADC 214). The first mixer 208-1 and the second mixer 208-2 are coupled to a local oscillator 216. Although not explicitly shown, the digital-to-analog converter 206 of the transmitter 202 and the analog-to-digital converter 214 of the receiver 204 can be coupled to the application processor 108 (of FIG. 1) or another processor associated with the wireless transceiver 120 (e.g., a modem).

In some implementations, the wireless transceiver 120 is implemented using multiple circuits (e.g., multiple integrated circuits), such as a transceiver circuit 236 and a radio-frequency front-end (RFFE) circuit 238. As such, the components that form the transmitter 202 and the receiver 204 are distributed across these circuits. As shown in FIG. 2, the transceiver circuit 236 includes the digital-to-analog converter 206 of the transmitter 202, the mixer 208-1 of the transmitter 202, the mixer 208-2 of the receiver 204, and the analog-to-digital converter 214 of the receiver 204. In other implementations, the digital-to-analog converter 206 and the analog-to-digital converter 214 can be implemented on another separate circuit that includes the application processor 108 or the modem. The radio-frequency front-end circuit 238 includes the amplifier 210 of the transmitter 202, the microacoustic filter 124-1 of the transmitter 202, the microacoustic filter 124-2 of the receiver 204, and the amplifier 212 of the receiver 204.

During transmission, the transmitter 202 generates an RF transmit signal 218, which is transmitted using the antenna 122-1. To generate the RF transmit signal 218, the digital-to-analog converter 206 provides a pre-upconversion transmit signal 220 to the first mixer 208-1. The pre-upconversion transmit signal 220 can be a baseband signal or an intermediate-frequency signal. The first mixer 208-1 upconverts the pre-upconversion transmit signal 220 using a local oscillator (LO) signal 222 provided by the local oscillator 216. The first mixer 208-1 generates an upconverted signal, which is referred to as a pre-filter transmit signal 224. The pre-filter transmit signal 224 can be a radio-frequency signal and include some noise or unwanted frequencies, such as a harmonic frequency. The amplifier 210 amplifies the pre-filter transmit signal 224 and passes the amplified pre-filter transmit signal 224 to the first microacoustic filter 124-1.

The first microacoustic filter 124-1 filters the amplified pre-filter transmit signal 224 to generate a filtered transmit signal 226. As part of the filtering process, the first microacoustic filter 124-1 attenuates the noise or unwanted frequencies within the pre-filter transmit signal 224. The transmitter 202 provides the filtered transmit signal 226 to the antenna 122-1 for transmission. The transmitted filtered transmit signal 226 is represented by the RF transmit signal 218.

During reception, the antenna 122-2 receives an RF receive signal 228 and passes the RF receive signal 228 to the receiver 204. The second microacoustic filter 124-2 accepts the received RF receive signal 228, which is represented by a pre-filter receive signal 230. The second microacoustic filter 124-2 filters any noise or unwanted frequencies within the pre-filter receive signal 230 to generate a filtered receive signal 232.

The amplifier 212 of the receiver 204 amplifies the filtered receive signal 232 and passes the amplified filtered receive signal 232 to the second mixer 208-2. The second mixer 208-2 downconverts the amplified filtered receive signal 232 using the LO signal 222 to generate the downconverted receive signal 234. The analog-to-digital converter 214 converts the downconverted receive signal 234 into a digital signal, which can be processed by the application processor 108 or another processor associated with the wireless transceiver 120 (e.g., the modem).

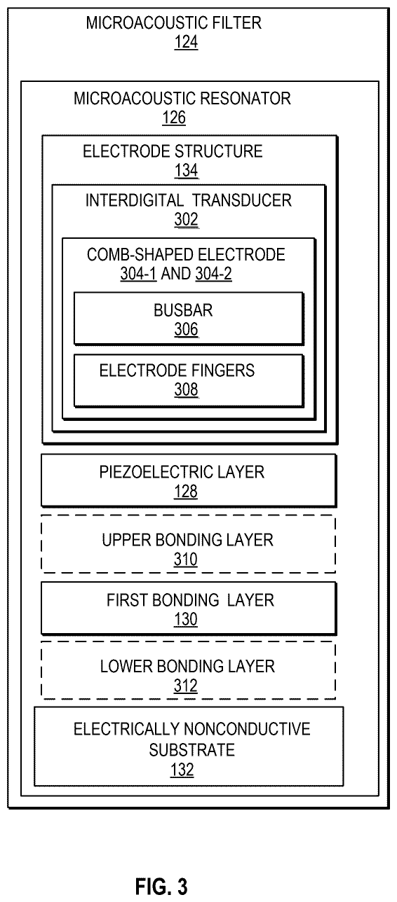

FIG. 2 illustrates one example configuration of the wireless transceiver 120. Other configurations of the wireless transceiver 120 can support multiple frequency bands and share an antenna 122 across multiple transceivers. One of ordinary skill in the art can appreciate the variety of other configurations for which microacoustic filters 124 may be included. For example, the microacoustic filters 124 can be integrated within duplexers or diplexers of the wireless transceiver 120. Example implementations of the microacoustic filter 124-1 or 124-2 is further described with respect to FIG. 3.

FIG. 3 illustrates example components of the microacoustic filter 124. In the depicted configuration, the microacoustic resonator 126 includes the piezoelectric layer 128 and the first bonding layer 130. In example implementations, the piezoelectric layer 128 can be implemented using a variety of different materials that exhibit piezoelectric properties (e.g., can transfer mechanical energy into electrical energy or electrical energy into mechanical energy). Example types of material include lithium niobate (LiNbO₃), lithium tantalate (LiTaO₃), or some combination thereof. In general, the material that forms the piezoelectric layer 128 may have a crystalline structure. This crystalline structure is defined by an ordered arrangement of particles (e.g., atoms, ions, or molecules). The orientation of the crystalline structure of the piezoelectric layer 128 can be defined by Euler angles lambda (λ), mu (μ), and theta (θ).

The electrode structure 134 comprises an electrically conductive material, such as metal, and can include one or more layers. The one or more layers can include one or more electrically conductive layers and can optionally include one or more adhesion layers. As an example, the electrically conductive layers can be composed of aluminum (Al), copper (Cu), silver (Ag), gold (Au), tungsten (W), silicon (Si), or some combination or alloyed version thereof. The adhesion layers can be composed of chromium (Cr), titanium (Ti), molybdenum (Mo), or some combination thereof.

The electrode structure 134 can include one or more interdigital transducers 302. The interdigital transducer 302 converts an electrical signal into an acoustic wave and converts the acoustic wave into a filtered electrical signal. The interdigital transducer 302 includes at least two comb-shaped electrodes 304-1 and 304-2. Each comb-shaped electrode 304-1 and 304-2 includes a busbar 306 (e.g., a conductive segment or rail) and multiple fingers 308 (e.g., electrode fingers) that extend from the busbar 306. Although not explicitly shown, the electrode structure 134 can also include two or more reflectors on the surface of the piezoelectric layer 128. In an example implementation, the interdigital transducer 302 may be arranged between two reflectors.

The substrate 132 is composed of material that is electrically non-conducting, even above 150 °C. In some examples, the substrate 132 comprises a polycrystalline spinel, such as magnesium aluminate (MgAl₂O₄). In some implementations, the substrate 132 is composed of multiple layers. The multiple layers can be formed using the same material or different materials.

The microacoustic SAW resonator 126 includes the first bonding layer 130 having the dual purposes of bonding the piezoelectric layer 128 to the substrate 132 and also offsetting or countering the TCF of the piezoelectric layer 128 to reduce the overall TCF of the microacoustic resonator 126. Optionally, the microacoustic SAW resonator 126 may also include one or both of an upper bonding layer 310 disposed between the piezoelectric layer 128 and the first bonding layer 130 and a lower bonding layer 312 disposed between the first bonding layer 130 and the substrate 132. In the presence of either one or both of the upper bonding layer 310 and the lower bonding layer 312, the first bonding layer 130 continues to counteract (e.g., reduce) the TCF of the piezoelectric layer 128 on the TCF of the microacoustic resonator 126 to enable the microacoustic resonator 126 to achieve a target TCF despite the piezoelectric layer 128 having a greater thickness needed to provide a desired capacitance.

In some examples, the microacoustic filter 124 can comprise the microacoustic resonator 126 connected to other resonators associated with different layers than the microacoustic resonator 126. In other aspects, the microacoustic filter 124 can be implemented as multiple interconnected microacoustic resonators 126, each having the same layers shown in FIG. 3 (e.g., the piezoelectric layer 128, the first bonding layer 130, and the substrate 132).

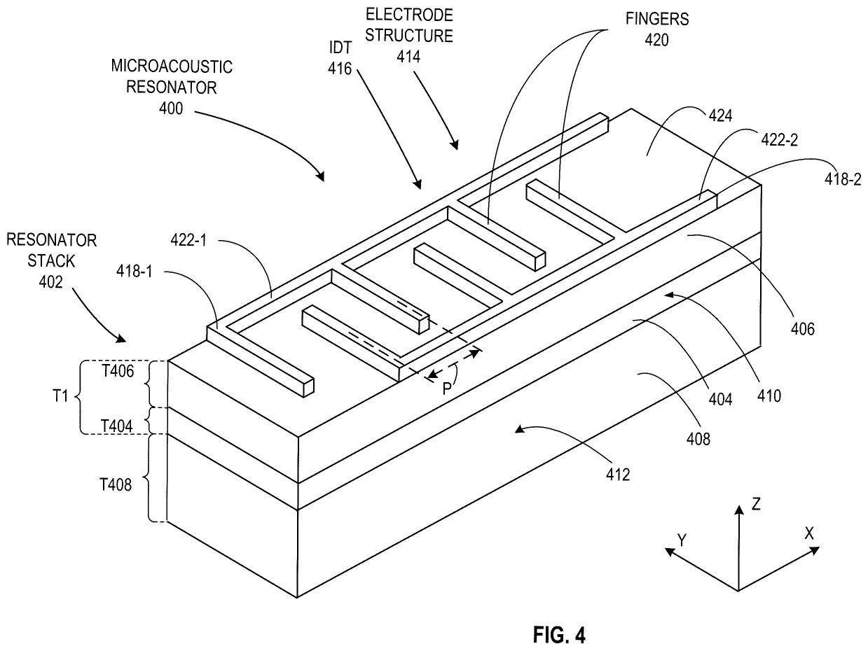

FIG. 4 illustrates a three-dimensional (3D) perspective view of a first example of a microacoustic SAW resonator 400 (“microacoustic resonator 400”) comprising a resonator stack 402 that includes a first bonding layer 404 between a piezoelectric layer 406 and a substrate 408. The first bonding layer 404 may be formed of a first bonding material 410 comprising fluorinated silicon dioxide (SiOF) to provide a positive TCF that will offset a negative TCF of the piezoelectric layer 406 and also to bond the piezoelectric layer 406 to the substrate 408. The substrate 408 may be formed of a substrate material 412 that is referred to herein as being “electrically non-conductive”, which is defined in this context as having an electrical conductivity that remains below 0.0001 Siemens/meter (10⁻⁴ S/m) even at temperatures exceeding 150 °C or approximately 423 degrees Kelvin. In contrast, the electrical conductivity of Si (silicon) at room temperature (e.g., 23.9 °C or 297 °K) is approximately 0.01 Siemens/meter (10⁻² S/m) and this value increases with temperature, particularly at temperatures of 150 °C and higher. Therefore, the microacoustic resonator 400 loses significantly less energy in the form of leakage currents through the substrate 408 compared to microacoustic resonators having silicon substrates. Although the substrate 408 has a very low conductivity (e.g., “non-conductive”), the substrate 408 has a thermal conductivity of at least 5 W/mK (Watts per meter Kelvin) (e.g., up to 17 W/mK or higher) in the anticipated range of operating temperatures of the microacoustic resonator 400 in a computing device. In some examples, the substrate material 412 comprises a polycrystalline spinel, such as magnesium aluminate (MgAl₂O₄). The substrate material 412 may be another type of polycrystalline spinel. In some examples, the substrate material 412 may be another type of material that is electrically non-conductive at temperatures exceeding 150 °C.

The microacoustic resonator 400 is a SAW type resonator that includes an electrode structure 414, which can include one or more interdigital transducers (IDTs) 416. In FIG. 4, the interdigital transducer 416 is shown to have two comb-shaped structures 418-1 and 418-2 with fingers 420 extending along a surface 424 of the piezoelectric layer 406 in a Y-axis direction from busbars 422-1 and 422-2 that extend in an X-axis direction along the surface 424. The surface 424 extends in a plane extending the X-axis direction and the Y-axis direction. The X-axis, Y-axis, and Z-axis are perpendicular or orthogonal to each other. Thus, a thickness orthogonal to the substrate 408 extends in the Z-axis direction. The fingers 420 are arranged in an interlocking or interdigitated arrangement between the two busbars 422-1 and 422-2 of the interdigital transducer 416. In other words, the fingers 420 connected to the first busbar 422-1 extend towards the second busbar 422-2 but do not contact the second busbar 422-2. Likewise, the fingers 420 connected to the second busbar 422-2 extend towards the first busbar 422-1 but do not contact the first busbar 422-1.

In the X-axis direction along the busbars 422-1, 422-2, a portion of one finger 420 overlaps with a portion of an adjacent finger 420 in a central region, which may be referred to as the aperture, track, or active region where electric fields are produced between fingers 420 to cause an acoustic wave to form at least in this region of the piezoelectric layer 406.

In FIG. 4, the surface 424 of the piezoelectric layer 406 is parallel to a plane formed by the X-axis and the Y-axis. The busbars 422-1, 422-2 of the interdigital transducer 416 are oriented to be parallel to the X-axis. The fingers 420 of the interdigital transducer 416 are oriented to extend parallel to the Y-axis. The fingers 420 generate an electric field in a direction that is substantially parallel to the X-axis. Due to the crystalline structure and orientation of the piezoelectric layer 406, the electric field excites the longitudinal mode within the piezoelectric layer 406. A resonant frequency of the acoustic waves excited in the piezoelectric layer 406 may depend on a pitch P or center-to-center spacing of the fingers 420 in the X-axis direction. For example, the pitch P of the fingers 420 may be determined as half of a wavelength λ (e.g., λ/2) of the desired resonant frequency of the microacoustic resonator 400. Materials from which the interdigital transducer 416 may be formed include aluminum (Al), copper (Cu), chromium (Cr), titanium (Ti), silicon (Si), and alloys thereof.

Using the piezoelectric effect, the acoustic wave forms within the piezoelectric layer 406 based on a time-varying input voltage signal in the interdigital transducer 416. Modified acoustic waves interact with the interdigital transducer 416 or another interdigital transducer within the electrode structure 414 (not shown in FIG. 4) to generate a modified output voltage signal. In particular, the piezoelectric layer 406 generates an alternating electric field due to the mechanical stress generated by the acoustic wave. The output signal from the microacoustic resonator 400 may be further processed by an arrangement of additional microacoustic resonators to produce a filtered RF signal that may be the filtered transmit signal 226, or the filtered receive signal 232 of FIG. 2.

It should be appreciated that while a certain number of fingers 420 are illustrated in FIG. 4, the number of actual fingers and lengths and widths of the fingers and busbars may be different in an actual implementation. Such parameters depend on the particular application and desired filter characteristics. For example, as noted above, the pitch P of the fingers 420 is set according to a desired resonant wavelength (e.g., λ) of the microacoustic resonator 400.

In addition, the thicknesses of layers making up the microacoustic resonator 400 may also be expressed in relation to the wavelength λ of the resonant frequency. The first bonding layer 404 may have a thickness T404 in a range of two (2) to five (5) percent (%) of the pitch P, where the pitch P is approximately half of the wavelength λ (λ/2). In some examples, the thickness T404 may be in a range from three (3) to four (4) percent (%) of the pitch P. In some examples, the thickness T404 may be up to ten (10) percent (%) of the pitch P. The piezoelectric layer 406 may have a thickness T406 in a direction orthogonal to the substrate 408, where the thickness T406 may be based on the wavelength λ. A combined thickness T1 including the thickness T404 of the first bonding layer 404 and the thickness T406 of the piezoelectric layer 406 is approximately equal to the pitch P (e.g., T1 is approximately equal to P). In some examples, the thickness T1 is in a range of 90% to 110% of the pitch P. In some examples, the thickness T1 is in a range of 95% to 105% of the pitch P. A thickness T408 of the substrate 408 may be at least fifteen times (15×) the wavelength λ.

In one example, for a wavelength λ of two (2) microns (μm), the pitch P may be one (1) μm, the thickness T406 of the piezoelectric layer 406 may be 1 μm, the thickness T404 of the first bonding layer 404 may be thirty (30) nanometers (nm), and the thickness T408 of the substrate 408 may be at least 75 μm.

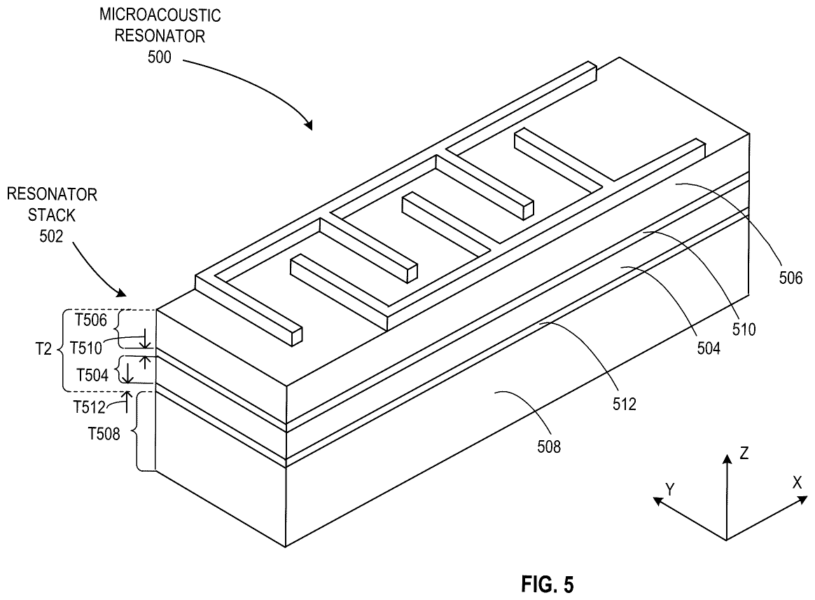

FIG. 5 illustrates a 3D perspective view of a second example of a microacoustic SAW resonator 500 (“microacoustic resonator 500”) comprising a resonator stack 502 that includes a first bonding layer 504 between a piezoelectric layer 506 and a substrate 508. The first bonding layer 504 may be formed of SiOF to make the TCF of the microacoustic resonator 500 more positive, offsetting an effect of the piezoelectric layer 506 that makes the TCF of the microacoustic resonator 500 more negative.

The substrate 508 is electrically non-conductive, having an electrical conductivity that remains below 0.0001 Siemens/meter (10⁻⁴ S/m) even at temperatures exceeding 150 °C or approximately 423 degrees Kelvin. In contrast, the electrical conductivity of Si (silicon) at room temperature (e.g., 23.9 °C or 297 °K) is approximately 0.01 (10⁻² S/m) and this value increases with temperature, particularly at temperatures of 150 °C and higher. Therefore, the microacoustic resonator 500 loses significantly less energy in the form of leakage currents through the substrate compared to microacoustic filters having Si substrates.

The first bonding layer 504 may also bond to one or both of the piezoelectric layer 506 and the substrate 508. In some examples, as shown in FIG. 5, the microacoustic resonator 500 may include one or both of an upper bonding layer 510 and a lower bonding layer 512 to improve bonding of the piezoelectric layer 506 to the substrate 508. The upper bonding layer 510 and the lower bonding layer 512 may each comprise one or more of silicon dioxide (SiO₂), silicon nitride (SiN), and aluminum nitride (AlN). In some examples, the microacoustic resonator 500 may include the upper bonding layer 510 but not a lower bonding layer 512. In some examples, the microacoustic resonator 500 may include the lower bonding layer 512 but not the upper bonding layer 510. In some examples, the microacoustic resonator 500 may include both of the upper bonding layer 510 and the lower bonding layer 512. A combined thickness T2 including a thickness T506 of the piezoelectric layer 506, a thickness T504 of the first bonding layer 504, and one or both of thickness T510 of the upper bonding layer 510 and thickness T512 of the lower bonding layer 512 may be expressed in relation to a wavelength λ of the microacoustic resonator 500. That is, the thickness T2 is approximately equal to (e.g., in the range of 90% to 110% of) the pitch P, where P=Λ/2. In some examples, the thickness T2 is in a range of 95% to 105% of the pitch P. A thickness T508 of the substrate 508 may be at least fifteen times (15×) the wavelength λ of the microacoustic resonator 500.

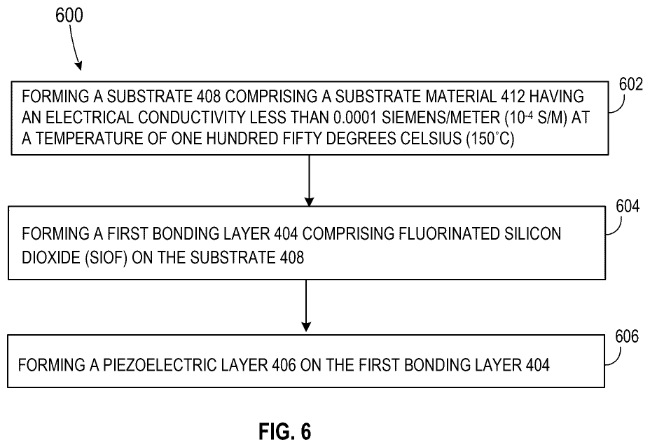

FIG. 6 is a flowchart of a method 600 of fabricating a microacoustic SAW resonator 400 described in FIG. 4, the method comprising: forming a substrate 408 comprising a substrate material 412 having an electrical conductivity less than 0.0001 Siemens/meter (10⁻⁴ S/m) at a temperature of 150 °C (block 602); forming a first bonding layer 404 comprising fluorinated silicon dioxide (SiOF) on the substrate 408 (block 604); and forming a piezoelectric layer 406 on the first bonding layer 404 (block 606).

Microacoustic filters may contain microacoustic SAW resonators in which the piezoelectric layers are excited in a longitudinal mode and in which a high-velocity layer is included to minimize irradiated energy propagation into the carrier substrate. Examples of such microacoustic filters, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, laptop computer, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, a drone, and a multicopter.

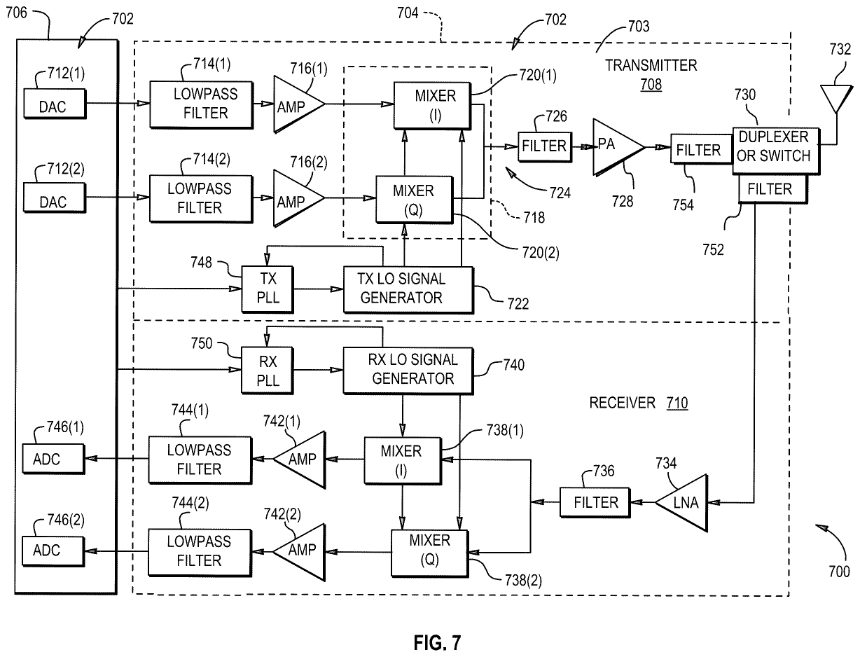

FIG. 7 illustrates an exemplary wireless communications device 700 that includes radio-frequency (RF) components formed from one or more integrated circuits (ICs) 702, wherein any of the ICs 702 may include microacoustic SAW resonators including a first bonding layer of fluorinated silicon dioxide (SiOF) to bond a piezoelectric layer to a substrate that is electrically non-conductive at temperatures exceeding 150 °C, as shown in FIGS. 4 and 5. The wireless communications device 700 may include or be provided in any of the above-referenced devices, as examples. As shown in FIG. 7, the wireless communications device 700 includes a transceiver 704 and a data processor 706. The data processor 706 may include a memory to store data and program codes. The transceiver 704 includes a transmitter 708 and a receiver 710 that support bi-directional communications. In general, the wireless communications device 700 may include any number of transmitters 708 and/or receivers 710 for any number of communication systems and frequency bands. All or a portion of the transceiver 704 may be implemented on one or more analog ICs, RF ICs (RFICs), mixed-signal ICs, etc.

The transmitter 708 or the receiver 710 may be implemented with a super-heterodyne architecture or a direct-conversion architecture. In the super-heterodyne architecture, a signal is frequency-converted between RF and baseband in multiple stages, for example, from RF to an intermediate frequency (IF) in one stage and then from IF to baseband in another stage for the receiver 710. In the direct-conversion architecture, a signal is frequency-converted between RF and baseband in one stage. The super-heterodyne and direct-conversion architectures may use different circuit blocks and/or have different requirements. In the wireless communications device 700 in FIG. 7, the transmitter 708 and the receiver 710 are implemented with the direct-conversion architecture.

In the transmit path, the data processor 706 processes data to be transmitted and provides I and Q analog output signals to the transmitter 708. In the exemplary wireless communications device 700, the data processor 706 includes digital-to-analog converters (DACs) 712(1), 712(2) for converting digital signals generated by the data processor 706 into the I and Q analog output signals (e.g., I and Q output currents) for further processing.

Within the transmitter 708, lowpass filters 714(1), 714(2) filter the I and Q analog output signals, respectively, to remove undesired signals caused by the prior digital-to-analog conversion. Amplifiers (AMPs) 716(1), 716(2) amplify the signals from the lowpass filters 714(1), 714(2), respectively, and provide I and Q baseband signals. An upconverter 718 upconverts the I and Q baseband signals with I and Q transmit (TX) local oscillator (LO) signals through mixers 720(1), 720(2) from a TX LO signal generator 722 to provide an upconverted signal 724. A filter 726 filters the upconverted signal 724 to remove undesired signals caused by the frequency up-conversion as well as noise in a receive frequency band. A power amplifier (PA) 728 amplifies the upconverted signal 724 from the filter 726 to obtain the desired output power level and provides a transmit RF signal. The transmit RF signal is routed through a duplexer or switch 730 and transmitted via an antenna 732.

In the receive path, the antenna 732 receives signals transmitted by base stations and provides a received RF signal, which is routed through the duplexer or switch 730 and provided to a low noise amplifier (LNA) 734. The duplexer or switch 730 is designed to operate with a specific receive (RX)-to-TX duplexer frequency separation, such that RX signals are isolated from TX signals. The received RF signal is amplified by the LNA 734 and filtered by a filter 736 to obtain a desired RF input signal. Down-conversion mixers 738(1), 738(2) mix the output of the filter 736 with I and Q RX LO signals (i.e., LO_I and LO_Q) from an RX LO signal generator 740 to generate I and Q baseband signals. The I and Q baseband signals are amplified by AMPs 742(1), 742(2) and further filtered by lowpass filters 744(1), 744(2) to obtain I and Q analog input signals, which are provided to the data processor 706. In this example, the data processor 706 includes analog-to-digital converters (ADCs) 746(1), 746(2) for converting the analog input signals into digital signals to be further processed by the data processor 706.

In the wireless communications device 700 of FIG. 7, the TX LO signal generator 722 generates the I and Q TX LO signals used for frequency up-conversion, while the RX LO signal generator 740 generates the I and Q RX LO signals used for frequency down-conversion. Each LO signal is a periodic signal with a particular fundamental frequency. A TX phase-locked loop (PLL) circuit 748 receives timing information from the data processor 706 and generates a control signal used to adjust the frequency and/or phase of the TX LO signals from the TX LO signal generator 722. Similarly, an RX PLL circuit 750 receives timing information from the data processor 706 and generates a control signal used to adjust the frequency and/or phase of the RX LO signals from the RX LO signal generator 740.

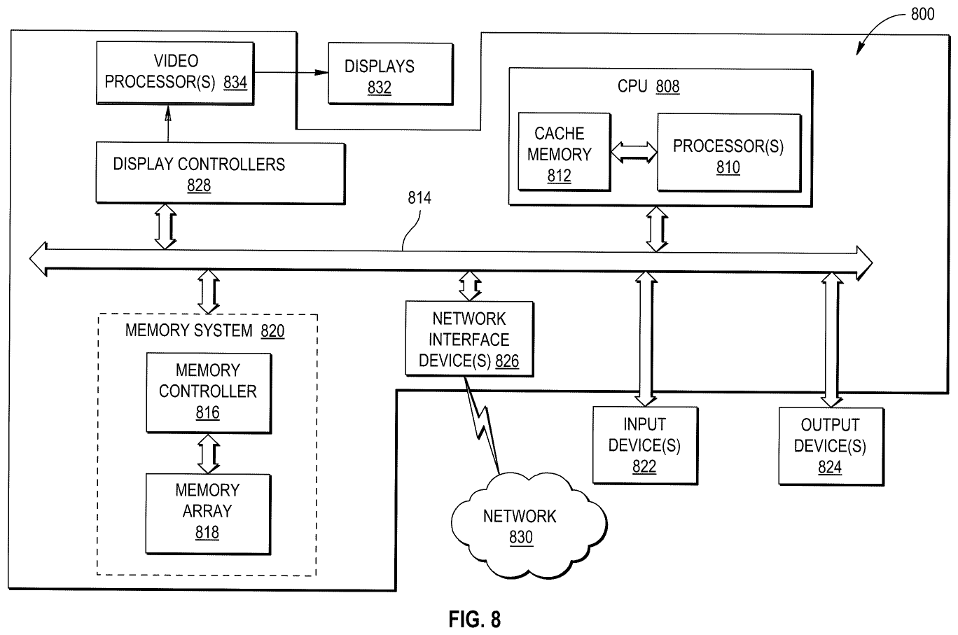

In this regard, FIG. 8 illustrates an example of a processor-based system 800 that can include microacoustic resonators with a first bonding layer of fluorinated silicon dioxide (SiOF) to bond a piezoelectric layer to a substrate that is electrically non-conductive at temperatures exceeding 150 °C, as shown in FIGS. 4 and 5. The processor-based system 800 includes a central processing unit (CPU) 808 that includes one or more processors 810, which may also be referred to as CPU cores or processor cores. The CPU 808 may have cache memory 812 coupled to the CPU 808 for rapid access to temporarily stored data. The CPU 808 is coupled to a system bus 814 and can intercouple controller and controlled devices included in the processor-based system 800. As is well known, the CPU 808 communicates with these other devices by exchanging address, control, and data information over the system bus 814. For example, the CPU 808 can communicate bus transaction requests to a memory controller 816, as an example of a controlled device. Although not illustrated in FIG. 8, multiple system buses 814 could be provided, wherein each system bus 814 constitutes a different fabric.

Other controller and controlled devices can be connected to the system bus 814. As illustrated in FIG. 8, these devices can include a memory system 820 that includes the memory controller 816 and a memory array(s) 818, one or more input devices 822, one or more output devices 824, one or more network interface devices 826, and one or more display controllers 828, as examples. The input device(s) 822 can include any type of input device, including, but not limited to, input keys, switches, voice processors, etc. The output device(s) 824 can include any type of output device, including, but not limited to, audio, video, other visual indicators, etc. The network interface device(s) 826 can be any device configured to allow an exchange of data to and from a network 830. The network 830 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 826 can be configured to support any type of communications protocol desired.

The CPU 808 may also be configured to access the display controller(s) 828 over the system bus 814 to control information sent to one or more displays 832. The display controller(s) 828 sends information to the display(s) 832 to be displayed via one or more video processor(s) 834, which processes the information to be displayed into a format suitable for the display(s) 832. The display(s) 832 can include any type of display, including, but not limited to, a cathode ray tube (CRT), a liquid crystal display (LCD), a plasma display, a light emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer-readable medium wherein any such instructions are executed by a processor or other processing device, or combinations of both. The devices and components described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from and write information to the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

Implementation examples are described in the following numbered clauses:
1. A microacoustic surface acoustic wave (SAW) resonator comprising:
   a substrate comprising a substrate material having an electrical conductivity less than 0.0001 Siemens/meter (10⁻⁴ S/m) at a temperature of one hundred fifty degrees Celsius (150 °C);
   a piezoelectric layer; and
   a first bonding layer comprising fluorinated silicon dioxide (SiOF) disposed between the piezoelectric layer and the substrate.
2. The microacoustic SAW resonator of clause 1, wherein the substrate material comprises a polycrystalline spinel.
3. The microacoustic SAW resonator of clause 2, wherein the polycrystalline spinel comprises magnesium aluminate (MgAl₂O₄).
4. The microacoustic SAW resonator of any of clauses 1-3, wherein the substrate material has a thermal conductivity of at least five watts per meter Kelvin (W/mK) at 150 °C.
5. The microacoustic SAW resonator of any of clauses 1-4, wherein the first bonding layer has a thickness in a direction orthogonal to the substrate of at least thirty (30) nanometers (nm).
6. The microacoustic SAW resonator of any of clauses 1-5, wherein the piezoelectric layer comprises one or both of lithium niobate (LiNbO₃) and lithium tantalate (LiTaO₃).
7. The microacoustic SAW resonator of any of clauses 1-6, wherein the piezoelectric layer has a first thickness in a direction orthogonal to the substrate in a range from five hundred (500) nanometers (nm) to one (1) micron (μm).
8. The microacoustic SAW resonator of clause 7, wherein the first bonding layer has a second thickness in the direction orthogonal to the substrate that is in a range of three percent (3%) to seven percent (7%) of the first thickness of the piezoelectric layer.
9. The microacoustic SAW resonator of clause 7, wherein the first bonding layer has a second thickness in the direction orthogonal to the substrate that is up to twenty (20) percent (20%) of the first thickness of the piezoelectric layer.
10. The microacoustic SAW resonator of clause 8 or 9, further comprising an electrode structure comprising:
   a first comb-shaped electrode comprising first electrode fingers extending in a first direction on a surface of the piezoelectric layer; and
   a second comb-shaped electrode comprising second electrode fingers extending in the first direction on the surface of the piezoelectric layer,
   wherein:
      the second electrode fingers are separated from the first electrode fingers by a first distance in a second direction orthogonal to the first direction; and
      a combined thickness of the first thickness of the piezoelectric layer and the second thickness of the first bonding layer is in a range of 90% to 110% of the first distance between the second electrode fingers and the first electrode fingers.
11. The microacoustic SAW resonator of any of clauses 8-10, wherein the substrate has a third thickness of at least 75μm.
12. The microacoustic SAW resonator of any of clauses 1-11, further comprising an upper bonding layer disposed between the piezoelectric layer and the first bonding layer.
13. The microacoustic SAW resonator of any of clauses 1-12, further comprising a lower bonding layer disposed between the first bonding layer and the substrate.
14. The microacoustic SAW resonator of clause 12, further comprising a lower bonding layer disposed between the first bonding layer and the substrate.
15. The microacoustic SAW resonator of clause 14, wherein the lower bonding layer and the upper bonding layer each comprise one of silicon dioxide (SiO₂), silicon nitride (SiN), and aluminum nitride (AlN).
16. The microacoustic SAW resonator of any of clauses 1-15, integrated into a device selected from a group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.
17. A method of fabricating a microacoustic surface acoustic wave (SAW) resonator, the method comprising:
   forming a substrate comprising a substrate material comprising a polycrystalline spinel having an electrical conductivity that is less than 0.0001 Siemens/meter (10⁻⁴ S/m) at a temperature of one hundred fifty degrees Celsius (150 °C);
   forming a piezoelectric layer on a first bonding layer; and
   forming the first bonding layer comprising fluorinated silicon dioxide (SiOF) between the substrate and the piezoelectric layer.
18. A microacoustic surface acoustic wave (SAW) resonator comprising:
   a substrate comprising a polycrystalline spinel comprising magnesium aluminate (MgAl₂O₄);
   a piezoelectric layer; and
   a first bonding layer comprising fluorinated silicon dioxide (SiOF) disposed between the piezoelectric layer and the substrate.
19. The microacoustic SAW resonator of clause 18, wherein the first bonding layer has a thickness in a direction orthogonal to the substrate of at least thirty (30) nanometers (nm).
20. The microacoustic SAW resonator of clause 18 or 19, wherein the piezoelectric layer comprises one or both of lithium niobate (LiNbO₃) and lithium tantalate (LiTaO₃).

What is claimed is:

1. A microacoustic surface acoustic wave (SAW) resonator comprising:
a substrate comprising a substrate material having an electrical conductivity less than 0.0001 Siemens/meter (10⁻⁴ S/m) at a temperature of one hundred fifty degrees Celsius (150 °C);
a piezoelectric layer; and
a first bonding layer comprising fluorinated silicon dioxide (SiOF) disposed between the piezoelectric layer and the substrate.

2. The microacoustic SAW resonator of claim 1, wherein the substrate material comprises a polycrystalline spinel.

3. The microacoustic SAW resonator of claim 2, wherein the polycrystalline spinel comprises magnesium aluminate (MgAl₂O₄).

4. The microacoustic SAW resonator of claim 1, wherein the substrate material has a thermal conductivity of at least five watts per meter Kelvin (W/mK) at 150 °C.

5. The microacoustic SAW resonator of claim 1, wherein the first bonding layer has a thickness in a direction orthogonal to the substrate of at least thirty (30) nanometers (nm).

6. The microacoustic SAW resonator of claim 1, wherein the piezoelectric layer comprises one or both of lithium niobate (LiNbO₃) and lithium tantalate (LiTaO₃).

7. The microacoustic SAW resonator of claim 1, wherein the piezoelectric layer has a first thickness in a direction orthogonal to the substrate in a range from five hundred (500) nanometers (nm) to one (1) micron (μm).

8. The microacoustic SAW resonator of claim 7, wherein the first bonding layer has a second thickness in the direction orthogonal to the substrate that is in a range of three percent (3%) to seven percent (7%) of the first thickness of the piezoelectric layer.

9. The microacoustic SAW resonator of claim 7, wherein the first bonding layer has a second thickness in the direction orthogonal to the substrate that is up to twenty (20) percent (20%) of the first thickness of the piezoelectric layer.

10. The microacoustic SAW resonator of claim 8, further comprising an electrode structure comprising:
a first comb-shaped electrode comprising first electrode fingers extending in a first direction on a surface of the piezoelectric layer; and
a second comb-shaped electrode comprising second electrode fingers extending in the first direction on the surface of the piezoelectric layer,
wherein:
the second electrode fingers are separated from the first electrode fingers by a first distance in a second direction orthogonal to the first direction; and
a combined thickness of the first thickness of the piezoelectric layer and the second thickness of the first bonding layer is in a range of 90% to 110% of the first distance between the second electrode fingers and the first electrode fingers.

11. The microacoustic SAW resonator of claim 8, wherein the substrate has a third thickness of at least 75 μm.

12. The microacoustic SAW resonator of claim 1, further comprising an upper bonding layer disposed between the piezoelectric layer and the first bonding layer.

13. The microacoustic SAW resonator of claim 1, further comprising a lower bonding layer disposed between the first bonding layer and the substrate.

14. The microacoustic SAW resonator of claim 12, further comprising a lower bonding layer disposed between the first bonding layer and the substrate.

15. The microacoustic SAW resonator of claim 14, wherein the lower bonding layer and the upper bonding layer each comprise one of silicon dioxide (SiO₂), silicon nitride (SiN), and aluminum nitride (AlN).

16. The microacoustic SAW resonator of claim 1, integrated into a device selected from a group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.

17. A method of fabricating a microacoustic surface acoustic wave (SAW) resonator, the method comprising:
forming a substrate comprising a substrate material comprising a polycrystalline spinel having an electrical conductivity that is less than 0.0001 Siemens/meter (10⁻⁴ S/m) at a temperature of one hundred fifty degrees Celsius (150 °C);
forming a piezoelectric layer on a first bonding layer; and
forming the first bonding layer comprising fluorinated silicon dioxide (SiOF) between the substrate and the piezoelectric layer.

18. A microacoustic surface acoustic wave (SAW) resonator comprising:
a substrate comprising a polycrystalline spinel comprising magnesium aluminate (MgAl₂O₄);
a piezoelectric layer; and
a first bonding layer comprising fluorinated silicon dioxide (SiOF) disposed between the piezoelectric layer and the substrate.

19. The microacoustic SAW resonator of claim 18, wherein the first bonding layer has a thickness in a direction orthogonal to the substrate of at least thirty (30) nanometers (nm).

20. The microacoustic SAW resonator of claim 18, wherein the piezoelectric layer comprises one or both of lithium niobate (LiNbO₃) and lithium tantalate (LiTaO₃).
